(19) United States
(12) Patent Application Publication
(10) Pub. No.: US 2013/0320335 A1
(43) Pub. Date: Dec. 5, 2013

(54) SEMICONDUCTOR DEVICE AND METHOD FOR MANUFACTURING THE SAME

(71) Applicant: Semiconductor Energy Laboratory Co., Ltd., Atsugi-shi (JP)

(72) Inventor: Shunpei YAMAZAKI, Setagaya (JP)

(21) Appl. No.: 13/903,272

(22) Filed: May 28, 2013

(30) Foreign Application Priority Data
Jun. 1, 2012 (JP) 2012-126607

(51) Int. Cl. H01L 29/12; H01L 21/02

(52) U.S. Cl. CPC H01L 29/12; H01L 21/02104
USPC 257/43; 438/104

(57) ABSTRACT

A semiconductor device is provided which is used as a power device for a high-power application, includes an oxide semiconductor, and has high withstand voltage and high reliability. A semiconductor device for a high-power application with high productivity is also provided. In a crystal part included in an oxide semiconductor film having a crystalline structure, a c-axis is aligned in a direction parallel to a normal vector of a surface where the oxide semiconductor film is formed or a normal vector of a surface of the oxide semiconductor film, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis.

### BACKGROUND OF THE INVENTION

1. Field of the Invention

An embodiment of the present invention relates to a semiconductor device including an oxide semiconductor and a method for manufacturing the semiconductor device.

In this specification, a semiconductor device generally means a device which can function by utilizing semiconductor characteristics. For example, a power device, an integrated circuit and a power supply device including the power device, an electronic device including the same, and the like are all semiconductor devices.

2. Description of the Related Art

As a semiconductor device used for a power device, a power device manufactured with the use of a silicon-based material is widely prevalent. However, the performance of a power device including silicon is reaching its limit, and it is becoming difficult to achieve higher performance.

The power device including silicon has a narrow band gap; therefore, the operation range is limited at high temperature. Thus, in recent years, a power device including SiC or GaN, which has a wide band gap, has been developed.

Patent Documents 1 and 2 disclose the use of an oxide semiconductor in a semiconductor device which is used as a power device for a high-power application. Patent Document 3 discloses a vertical transistor including an oxide semiconductor.

### REFERENCE

[Patent Document 1] Japanese Published Patent Application No. 2011-91382
[Patent Document 2] Japanese Published Patent Application No. 2011-172217
[Patent Document 3] Japanese Published Patent Application No. 2011-129898

### SUMMARY OF THE INVENTION

It is preferable to use a highly heat dissipating semiconductor substrate as a substrate where a transistor or a rectifier element used in a semiconductor device for a high-power application is provided. Among semiconductor substrates of a variety of materials, typical examples of highly heat dissipating substrates include a single crystal silicon substrate, a SiC substrate, and the like.

When an insulating film containing silicon such as a thermal oxide film is formed on a single crystal silicon substrate or a SiC substrate and an oxide semiconductor film is formed over and in contact with the insulating film, silicon or the like might enter the oxide semiconductor film. In addition, when an oxide semiconductor film is formed over a thermal oxide film which is formed using a mixed gas of hydrogen chloride and oxygen, and then heat treatment is performed, chlorine might enter the oxide semiconductor film. The entry of chlorine into the oxide semiconductor film may cause degradation of electrical characteristics of a semiconductor device.

It is one object to provide a semiconductor device which is used as a power device for a high-power application, includes an oxide semiconductor, and has high withstand voltage and high reliability.

It is another object to provide a semiconductor device for a high-power application with high productivity.

In one embodiment of the present invention disclosed in this specification, an oxide semiconductor film having a crystalline structure is used in a semiconductor device which is used as a power device for a high-power application.

In order to prevent silicon and chlorine from entering the oxide semiconductor film, a buffer layer is provided between a semiconductor substrate and the oxide semiconductor film. Further, the buffer layer is provided between the oxide semiconductor film and an oxide or nitride film formed over a surface of the semiconductor substrate.

As the buffer layer, a material film capable of blocking the diffusion of impurities contained in the semiconductor substrate, typically a film containing gallium, is used. Specifically, a gallium oxide film (GaOₓ (x>0)), an indium gallium oxide film, or an In—Ga—Zn-based oxide film formed using a target with an atomic ratio of In:Ga:Zn=1:3:2 is used.

One embodiment of the present invention disclosed in this specification is a method for manufacturing a semiconductor device, which includes the steps of: forming an oxide insulating film over a semiconductor substrate; forming a buffer layer over the oxide insulating film; forming an oxide semiconductor film over the buffer layer; and performing heat treatment on the oxide semiconductor film at a temperature higher than or equal to 900° C. and lower than or equal to 1500° C., thereby forming an oxide semiconductor film having a crystalline structure.

An embodiment obtained from the above embodiment is also included in the present invention, which is a semiconductor device including an oxide insulating film over a semiconductor substrate, a buffer layer over the oxide insulating film, and an oxide semiconductor film having a crystalline structure over the buffer layer.

One feature of a crystal part included in the oxide semiconductor film having a crystalline structure is that a c-axis is aligned in a direction parallel to a normal vector of a surface where the oxide semiconductor film is formed or a normal vector of a surface of the oxide semiconductor film, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis.

The oxide semiconductor film having a crystalline structure in each of the above embodiments can be referred to as a c-axis aligned crystalline oxide semiconductor (CAAC-OS) film. The CAAC-OS film is one of oxide semiconductor films including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm. In a transmission electron microscope (TEM) image, a boundary between crystal parts, that is, a grain boundary is not clearly observed. Thus, in the CAAC-OS film, a reduction in electron mobility due to the grain boundary is less likely to occur. According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface where the CAAC-OS film is formed (hereinafter, a surface where the CAAC-OS film is formed is referred to as a formation surface) or a top surface of the CAAC-OS film, and is arranged in parallel to the formation surface or the top surface of the CAAC-OS film. On the other hand, according to the TEM image of the CAAC-OS film observed in a direction substantially perpendicular to the sample surface (planar TEM image), metal atoms are arranged in a triangular or hexagonal configuration in the crystal parts. However, there is no regularity of arrangement of metal atoms between different crystal parts.

Note that, among crystal parts in the CAAC-OS film, the directions of the a-axis and the b-axis of one crystal part may be different from those of another crystal part. In this specification, a term “perpendicular” includes a range from 85° to 95°. In addition, a term “parallel” includes a range from −5° to 5°.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface where the oxide semiconductor film is formed in some cases. Further, when an impurity is added to the CAAC-OS film, crystallinity of the crystal part in a region to which the impurity is added is lowered in some cases.

Since the c-axes of the crystal parts included in the CAAC-OS film are aligned in the direction parallel to a normal vector of a surface where the CAAC-OS film is formed or a normal vector of a surface of the CAAC-OS film, the directions of the c-axes may be different from each other depending on the shape of the CAAC-OS film (the cross-sectional shape of the surface where the CAAC-OS film is formed or the cross-sectional shape of the surface of the CAAC-OS film). Note that when the CAAC-OS film is formed, the direction of c-axis of the crystal part is the direction parallel to a normal vector of the surface where the CAAC-OS film is formed or a normal vector of the surface of the CAAC-OS film. The crystal part is formed by film formation or by performing treatment for crystallization such as heat treatment after film formation.

For example, the CAAC-OS film is formed by a sputtering method with a polycrystalline oxide semiconductor sputtering target. When ions collide with the sputtering target, a crystal region included in the sputtering target may be separated from the target along an a-b plane; in other words, a sputtered particle having a plane parallel to an a-b plane (flat-plate-like sputtered particle or pellet-like sputtered particle) may flake off from the sputtering target. In that case, the flat-plate-like sputtered particle reaches a substrate while maintaining their crystal state, whereby the crystal state of the sputtering target is transferred to the substrate and the CAAC-OS film can be formed.

For the deposition of the CAAC-OS film, the following conditions are preferably used.

By reducing the impurity concentration during the deposition, the crystal state can be prevented from being broken by the impurities. For example, impurities (e.g., hydrogen, water, carbon dioxide, and nitrogen) which exist in the film formation chamber may be reduced. Furthermore, impurities in a deposition gas may be reduced. Specifically, a deposition gas whose dew point is −80° C. or lower, preferably −100° C. or lower is used.

By increasing the substrate heating temperature during the deposition, migration of a sputtered particle is likely to occur after the sputtered particle is attached to a substrate surface. Specifically, the substrate heating temperature during the deposition is higher than or equal to 100° C. and lower than or equal to 740° C., preferably higher than or equal to 200° C. and lower than or equal to 500° C. By increasing the substrate heating temperature during the deposition, when the flat-plate-like sputtered particle reaches the substrate, migration occurs on the substrate surface, so that a flat plane thereof is attached to the substrate.

Furthermore, it is preferable that the proportion of oxygen in the deposition gas be increased and the power be optimized in order to reduce plasma damage at the deposition. The proportion of oxygen in the deposition gas is 30 vol % or higher, preferably 100 vol %.

As an example of the sputtering target, an In—Ga—Zn—O compound target is described below.

The In—Ga—Zn—O compound target, which is polycrystalline, is made by mixing InO_{X} powder, GaO_{Y} powder, and ZnO_{Z} powder in a predetermined ratio, applying pressure, and performing heat treatment at a temperature higher than or equal to 1000° C. and lower than or equal to 1500° C. Note that X, Y and Z are given positive numbers. Here, the predetermined molar ratio of InO_{X} powder to GaO_{Y} powder and ZnO_{Z} powder is, for example, 2:2:1, 8:4:3, 3:1:1, 1:1:1, 4:2:3, or 3:1:2. The kinds of powder and the molar ratio for mixing powder may be determined as appropriate depending on the desired sputtering target.

In each of the above embodiments, the semiconductor substrate may be a single crystal silicon substrate, and the oxide insulating film may be a thermal oxide film. Since the buffer layer is provided between the oxide insulating film and the oxide semiconductor film in the above embodiment, even when hydrogen chloride is used for formation of the thermal oxide film, the diffusion of chlorine can be blocked by the buffer layer. When the oxide semiconductor film is formed by a sputtering method directly over a silicon oxide film that is the thermal oxide film, silicon might enter the oxide semiconductor film during sputtering. However, since the buffer layer is provided, silicon can be prevented from entering the oxide semiconductor film. The entry of impurities such as silicon into the oxide semiconductor film inhibits crystallization and is thus preferably prevented as much as possible.

In the oxide semiconductor film having a crystalline structure, an n-type region may be formed by selective addition of phosphorus, boron, or nitrogen. Another embodiment of the present invention is a method for manufacturing a semiconductor device, which includes the steps of: forming an oxide insulating film over a semiconductor substrate; forming a buffer layer over the oxide insulating film; forming an oxide semiconductor film having a crystalline structure over the buffer layer; selectively adding phosphorus, boron, or nitrogen to the oxide semiconductor film having a crystalline structure; and performing heat treatment on the oxide semiconductor film at a temperature higher than or equal to 900° C. and lower than or equal to 1500° C. after adding phosphorus, boron, or nitrogen.

A region to which phosphorus, boron, or nitrogen is selectively added in the oxide semiconductor film having the crystal structure tends to have low crystallinity. By leaving a crystal part in the oxide semiconductor film and performing heat treatment thereon at a temperature higher than or equal to 900° C. and lower than or equal to 1500° C., a CAAC-OS film can be formed again. The heat treatment at a temperature higher than or equal to 900° C. and lower than or equal to 1500° C. can increase the density of the oxide semiconductor film. Further, with the heat treatment at a temperature higher than or equal to 900° C. and lower than or equal to 1500° C., density and crystallinity which are in substantially the same level as those of a single crystal of an oxide semiconductor can be obtained.

The oxide insulating film in contact with the semiconductor substrate may be replaced with a nitride insulating film. Another embodiment of the present invention is a semiconductor device which includes a nitride insulating film over a semiconductor substrate, a buffer layer over the nitride insulating film, and an oxide semiconductor film having a crystalline structure over the buffer layer.

Needless to say, the insulating film in contact with the semiconductor substrate may be multilayered. For example, it is possible that a nitride insulating film is formed over and in contact with a semiconductor substrate, an oxide insulating film is formed over and in contact with the nitride insulating film, a buffer layer is formed over and in contact with the oxide insulating film, and an oxide semiconductor film is formed over and in contact with the buffer layer.

Examples of power devices which can be manufactured using the oxide semiconductor film having a crystalline structure (also referred to as oxide semiconductor power devices) include rectifier elements such as two-terminal diodes and switching elements such as three-terminal transistors. As transistors, a power metal oxide semiconductor FET (power MOSFET), a power metal semiconductor field effect transistor (power MESFET), an HFET, a junction field-effect transistor (JFET), and the like can be used as appropriate. As the power devices which can be manufactured using the oxide semiconductor film having a crystalline structure, a bipolar transistor, a gate turnoff thyristor, an insulated gate bipolar transistor (IGBT), and the like can be used as appropriate. Note that power loss due to switching can be reduced using a unipolar transistor such as a MOSFET or a MESFET, compared with the case of using a bipolar transistor such as an IGBT.

Next, hot-carrier degradation of a transistor including the oxide semiconductor film is described.

The hot-carrier degradation means deterioration of transistor characteristics, e.g., shift in threshold voltage or gate leakage, which is caused as follows: electrons that are accelerated to be rapid are injected in the vicinity of a drain in a channel into a gate insulating film and become fixed electric charge or form trap levels at the interface between the gate insulating film and the oxide semiconductor. The factors of the hot-carrier degradation are, for example, channel-hot-electron injection (CHE injection) and drain-avalanche-hot-carrier injection (DAHC injection).

Since the band gap of silicon is narrow, electrons are likely to be generated like an avalanche owing to an avalanche breakdown, and the number of electrons that are accelerated to be so rapid as to go over a barrier to the gate insulating film is increased. However, the oxide semiconductor film described in this embodiment has a wide band gap; therefore, the avalanche breakdown is unlikely to occur and resistance to the hot-carrier degradation is higher than that of silicon. For this reason, it can be said that a transistor formed using the oxide semiconductor film in this specification has a high drain breakdown voltage. Therefore, such a transistor is suitable for a power device such as an insulated-gate field-effect transistor (IGFET).

With the use of the oxide semiconductor film having a crystalline structure, it is possible to obtain an oxide semiconductor power device for a high-power application which has high withstand voltage and high reliability.

A SiC power device is manufactured through a complicated process using a method of forming an epitaxial layer. On the other hand, the oxide semiconductor film of the oxide semiconductor power device is formed using a sputtering method, and this makes it possible to obtain a semiconductor device for a high-power application with higher productivity than in the case of using the method of forming an epitaxial layer.

### BRIEF DESCRIPTION OF THE DRAWINGS

FIGS. 1A and 1B are cross-sectional views each illustrating one embodiment of the present invention.

FIGS. 2A and 2B are a top view and a cross-sectional view illustrating one embodiment of the present invention.

FIG. 3 is a perspective view illustrating one embodiment of the present invention.

FIGS. 4A and 4B are block diagrams each illustrating one embodiment of the present invention.

FIG. 5 is a block diagram illustrating one embodiment of the present invention.

FIGS. 6A and 6B each illustrate an application product of one embodiment of the present invention.

FIG. 7 is a cross-sectional view illustrating one embodiment of the present invention.

FIG. 8 is a circuit diagram illustrating one embodiment of the present invention.

FIG. 9 is a circuit diagram illustrating one embodiment of the present invention.

### DETAILED DESCRIPTION OF THE INVENTION

Embodiments of the present invention will be described in detail below with reference to drawings. Note that the present invention is not limited to the description below, and it is easily understood by those skilled in the art that modes and details of the present invention can be modified in various ways. In addition, the present invention should not be construed as being limited to the description in the embodiments given below.

### Embodiment 1

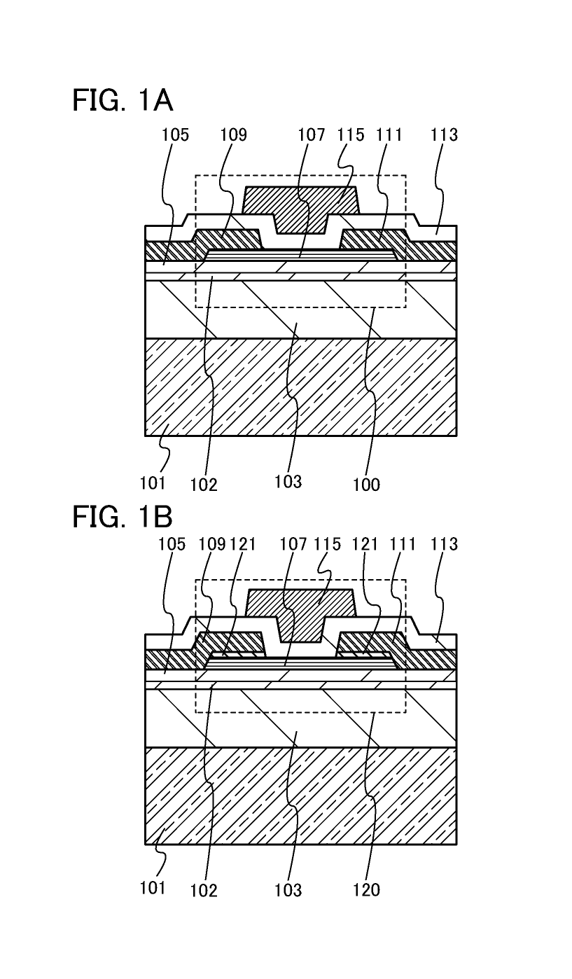

In this embodiment, a structure of a power MOSFET and a manufacturing method thereof will be described with reference to FIG. 1A.

A power device 100 illustrated in FIG. 1A is a power MOSFET, in which a semiconductor substrate 103 serves as a back gate, an insulating film 102 is provided over the semiconductor substrate 103, a buffer layer 105 is provided over the insulating film 102, an oxide semiconductor film 107 having a crystalline structure is provided over the buffer layer 105, a first terminal 109 and a second terminal 111 formed using a conductive layer are provided so as to partly cover the oxide semiconductor film 107 having a crystalline structure, an insulating film 113 is provided so as to cover the oxide semiconductor film 107 having a crystalline structure, the first terminal 109, and the second terminal 111, and a gate 115 formed using a conductive layer is provided over the insulating film 113 so as to partly overlap with both the first terminal 109 and the second terminal 111.

It is necessary that the semiconductor substrate 103 have at least heat resistance high enough to withstand heat treatment (900° C. or higher) which is performed later.

As the semiconductor substrate 103, a single crystal silicon substrate, a SiC substrate, a GaN substrate, a GaAs substrate, or the like is used. Alternatively, a compound semiconductor substrate of silicon germanium or the like or an SOI substrate may be used as the semiconductor substrate 103.

The insulating film 102 can be a single insulating film or a stack of insulating films selected from a silicon oxide film which is obtained by thermal oxidation or the like using hydrogen chloride or the like and a silicon oxide film, an oxynitride insulating film of silicon oxynitride, aluminum oxynitride, or the like, and a nitride oxide insulating film of silicon nitride oxide or the like which are obtained by a plasma chemical vapor deposition (CVD) method or the like. Note that “silicon nitride oxide” contains more nitrogen than oxygen, and “silicon oxynitride” contains more oxygen than nitrogen.

As the insulating film 102, a silicon nitride film obtained by a plasma CVD method or the like may be used. Note that in the case of using a silicon nitride film, it is preferable to use a silicon nitride film from which hydrogen or a hydrogen compound is hardly released by heat treatment after film formation, such as a silicon nitride film formed using a mixed gas of silane (SiH₄), nitrogen (N₂), and ammonia (NH₃) as a supply gas.

The buffer layer 105 can be formed using a single insulating film or a stack of insulating films selected from oxide insulating films of gallium oxide, indium gallium oxide, hafnium oxide, yttrium oxide, aluminum oxide, and the like. Among these materials, gallium oxide or indium gallium oxide containing a constituent element of the oxide semiconductor film is preferable. Alternatively, the buffer layer 105 may be formed using an In—Ga—Zn-based oxide film which is formed using a target with an atomic ratio of In:Ga:Zn=1:3:2.

The oxide semiconductor film 107 having a crystalline structure can be formed using an oxide containing at least In and containing a metal element M (M is Ga, Hf, Zn, Mg, Sn, or the like), e.g., a two-component metal oxide such as an In—Zn-based oxide, an In—Mg-based oxide, or an In—Ga-based oxide, a three-component metal oxide such as an In—Ga—Zn-based oxide (also referred to as IGZO), an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four—component metal oxide such as an In—Sn—Ga—Zn-based oxide, an In—Hf—Ga—Zn-based oxide, or an In—Sn—Hf—Zn-based oxide.

The oxide semiconductor film 107 having a crystalline structure is not limited to a single layer and may be multilayered; a stack of films having different compositions may be used. When a stack of films having different compositions is used as the oxide semiconductor film 107 having a crystalline structure, one film serves as a crystal nucleus to promote crystallization of another film. For example, a two-layer structure may be used, in which an In—Ga—Zn-based oxide film formed using a target with an atomic ratio of In:Ga:Zn=1:1:1 is stacked over an In—Ga—Zn-based oxide film formed using a target with an atomic ratio of In:Ga:Zn=3:1:2. When this two-layer structure is subjected to heat treatment, the two layers both become films having high crystallinity, which is a stack of films having the same crystal structure, i.e., CAAC-OS films. Alternatively, a three-layer structure may be used, in which an In—Ga—Zn-based oxide film formed using a target with an atomic ratio of In:Ga:Zn=3:1:2 is formed over an In—Ga—Zn-based oxide film formed using a target with an atomic ratio of In:Ga:Zn=1:1:1 and then an In—Ga—Zn-based oxide film formed using a target with an atomic ratio of In:Ga:Zn=1:1:1 is stacked thereover.

The thickness of the oxide semiconductor film 107 having a crystalline structure is set so that a depletion layer spreads in a channel region and the power device 100 can be turned off when negative voltage is applied between the gate 115 and the semiconductor substrate 103 serving as a back gate.

The first terminal 109 and the second terminal 111 can be formed using a metal element selected from aluminum, chromium, copper, tantalum, titanium, molybdenum, and tungsten; an alloy containing any of these metal elements as a component; an alloy containing these metal elements in combination; or the like. Further, one or more metal elements selected from manganese, magnesium, zirconium, and beryllium may be used. In addition, the first terminal 109 and the second terminal 111 may have a single-layer structure or a stacked-layer structure having two or more layers. For example, a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, a three-layer structure in which a titanium layer, an aluminum layer, and a titanium layer are stacked in this order, and the like can be given. Alternatively, a layer, an alloy layer, or a nitride layer, which contains aluminum and one or more elements selected from titanium, tantalum, tungsten, molybdenum, chromium, neodymium, and scandium may be used.

The first terminal 109 and the second terminal 111 can be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to use a stacked-layer structure formed using the above light-transmitting conductive material and the above metal element.

The insulating film 113 can be a single insulating film or a stack of insulating films selected from a silicon oxide film, an oxynitride insulating film of silicon oxynitride, aluminum oxynitride, or the like, and a nitride oxide insulating film of silicon nitride oxide or the like which are obtained by a plasma CVD method or the like. Note that a second buffer layer may be provided between the insulating film 113 and the oxide semiconductor film 107. The second buffer layer can be formed using a material which can be used for the buffer layer 105, as appropriate.

The gate 115 can be formed using a metal element selected from aluminum, chromium, copper, tantalum, titanium, molybdenum, and tungsten; an alloy containing any of these metal elements as a component; an alloy containing these metal elements in combination; or the like. Further, one or more metal elements selected from manganese, magnesium, zirconium, and beryllium may be used. In addition, the gate 115 may have a single-layer structure or a stacked-layer structure of two or more layers. For example, a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, a three-layer structure in which a titanium layer, an aluminum layer, and a titanium layer are stacked in this order, and the like can be given. Alternatively, a layer, an alloy layer, or a nitride layer, which contains aluminum and one or more elements selected from titanium, tantalum, tungsten, molybdenum, chromium, neodymium, and scandium may be used.

The gate 115 can be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to use a stacked-layer structure formed using the above light-transmitting conductive material and the above metal element.

Since the power device 100 illustrated in FIG. 1A includes the oxide semiconductor film 107 having a crystalline structure for the channel region, on-state resistance can be reduced and a large amount of current can flow.

A method for manufacturing the power device 100 illustrated in FIG. 1A will be described below.

The insulating film 102 is formed over the semiconductor substrate 103 serving as a back gate. The insulating film 102 is formed by thermal oxidation using hydrogen chloride. Alternatively, the insulating film 102 may be formed by high-density plasma CVD using microwaves (e.g., a frequency of 2.45 GHz) so as to be dense and have high withstand voltage and high quality.

Next, the buffer layer 105 is formed by a sputtering method, a CVD method, a coating method, a pulsed laser deposition method, or the like. As the buffer layer 105, a material film capable of blocking the diffusion of impurities contained in the semiconductor substrate 103 or the insulating film 102, typically a film containing gallium, is used.

Next, the oxide semiconductor film 107 having a crystalline structure is formed over the buffer layer 105.

The oxide semiconductor film 107 is preferably the one having a crystal structure right after deposition, which is obtained by deposition by a sputtering method at a relatively high deposition temperature. If the deposition temperature is set at 400° C. or higher for high density, later heat treatment at 900° C. or higher does not generate peeling or the like. Note that in the case where the oxide semiconductor film 107 has low crystallinity right after the deposition, the oxide semiconductor film 107 can be changed to have high crystallinity by performing heat treatment thereon.

Then, heat treatment is performed at a temperature higher than or equal to 900° C. and lower than or equal to 1500° C. in a vacuum atmosphere, a nitrogen atmosphere, an oxygen atmosphere, or a mixed atmosphere of nitrogen and oxygen. With the heat treatment at a temperature higher than or equal to 900° C. and lower than or equal to 1500° C., density and crystallinity which are in substantially the same level as those of a single crystal of an oxide semiconductor can be obtained.

In this embodiment, a CAAC-OS film is formed at a substrate temperature of 400° C. using an In—Ga—Zn-based oxide film which is formed using a target with an atomic ratio of In:Ga:Zn=1:1:1, and is then subjected to heat treatment at 950° C. Even after the heat treatment, in the oxide semiconductor film 107, a c-axis is aligned in a direction parallel to a normal vector of a surface where the oxide semiconductor film is formed or a normal vector of a surface of the oxide semiconductor film, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis.

Note that when the buffer layer 105 is exposed to a clean room atmosphere after the formation and the oxide semiconductor film is then formed, boron contained in the clean room atmosphere might be mixed at the interface between the buffer layer 105 and the oxide semiconductor film. Thus, it is preferable that the oxide semiconductor film be formed without exposure of the buffer layer 105 to the atmosphere after the formation. Both of them can be formed by a sputtering method and can be successively formed simply by changing targets.

Next, a resist is formed by a photolithography process over the oxide semiconductor film 107 having a crystalline structure, and the oxide semiconductor film is etched using the resist as a mask. Thus, an island-shaped oxide semiconductor film is formed. The island-shaped oxide semiconductor film is formed so as to have a tapered side surface. Note that the taper angle between the side surface of the oxide semiconductor film 107 having a crystalline structure and a surface of the semiconductor substrate is greater than or equal to 10° and less than or equal to 70°.

Next, the first terminal 109 and the second terminal 111 which serve as a source electrode and a drain electrode are formed in such a manner that a conductive layer is formed over the oxide semiconductor film 107 by a sputtering method, a CVD method, an evaporation method, or the like, and then the conductive layer is etched with the use of a resist formed by a photolithography process as a mask. When the first terminal 109 and the second terminal 111 are formed by a printing method, an inkjet method, or the like, the number of steps can be reduced.

Next, the insulating film 113 is formed over the buffer layer 105, the oxide semiconductor film 107, the first terminal 109, and the second terminal 111.

The insulating film 113 can be a single insulating film or a stack of insulating films selected from a silicon oxide film, an oxynitride insulating film of silicon oxynitride, aluminum oxynitride, or the like, and a nitride oxide insulating film of silicon nitride oxide or the like which are obtained by a plasma CVD method or the like.

Next, the gate 115 is formed over the insulating film 113. The gate 115 can be formed in such a manner that a conductive layer is formed over the insulating film 113 by a sputtering method, a CVD method, an evaporation method, or the like, and then the conductive layer is etched with the use of a resist formed by a photolithography process as a mask.

Through the above steps, the power device 100 including the oxide semiconductor film 107 having a crystalline structure for the channel region can be manufactured. Lastly, the power device 100 is fixed to a heat dissipation plate 101.

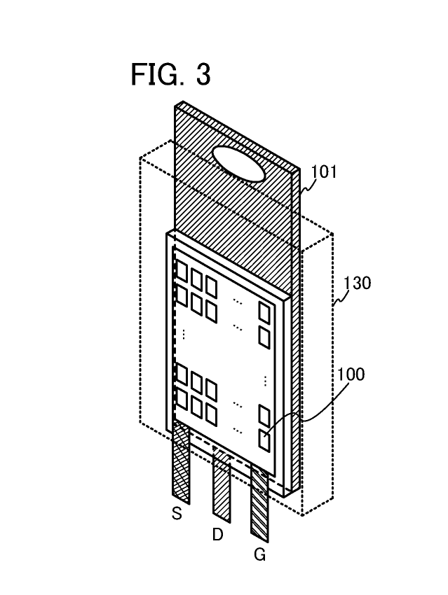

Note that the heat dissipation plate 101 can dissipate more heat when extending to the outside. For example, as illustrated in a perspective view in FIG. 3, the heat dissipation plate 101 provided with the power device 100 may extend to the outside of a housing 130.

As illustrated in FIG. 3, not only a terminal D and a terminal G but also part of the heat dissipation plate 101 can extend to the outside of the housing 130 for connection to an external element. In this case, an electrode extending from the heat dissipation plate 101 can be used as a terminal S which is connected to sources (or drains) of a plurality of power devices 100.

FIG. 1B illustrates an example of a power device 120 in which n-type regions 121 are provided over the oxide semiconductor film 107.

In the power device 120 illustrated in FIG. 1B, the n-type regions 121 are oxide semiconductor films containing phosphorus, boron, or nitrogen and having a crystalline structure. Contact resistance is lowered by formation of the n-type regions 121 between the first terminal 109 and the oxide semiconductor film 107 and between the second terminal 111 and the oxide semiconductor film 107.

Steps up to the step of forming the buffer layer 105 are the same; thus, steps after the step of forming the buffer layer 105 will be described. After the formation of the oxide semiconductor film having a crystalline structure, phosphorus, boron, or nitrogen is added to a region near the surface by plasma treatment or an ion implantation method. The region to which phosphorus, boron, or nitrogen is added tends to have lower crystallinity. Note that it is preferable that a crystal part remain under the region to which phosphorus, boron, or nitrogen is added. After the addition, heat treatment is performed at a temperature higher than or equal to 900° C. and lower than or equal to 1500° C. in a vacuum atmosphere, a nitrogen atmosphere, an oxygen atmosphere, or a mixed atmosphere of nitrogen and oxygen. This heat treatment can crystallize the region to which phosphorus, boron, or nitrogen is added.

Next, a resist is formed by a photolithography process over the region to which phosphorus, boron, or nitrogen is added, and the oxide semiconductor film is etched using the resist as a mask. Thus, an island-shaped oxide semiconductor film is formed.

Next, the first terminal 109 and the second terminal 111 which serve as a source electrode and a drain electrode are formed in such a manner that a conductive layer is formed over the oxide semiconductor film 107 by a sputtering method, a CVD method, an evaporation method, or the like, and then the conductive layer is etched with the use of a resist formed by a photolithography process as a mask. Then, the region to which phosphorus, boron, or nitrogen is added is selectively removed using the first terminal 109 and the second terminal 111 as a mask. Thus, the n-type regions 121 can be formed under the first terminal 109 and the second terminal 111.

Next, the insulating film 113 is formed over the buffer layer 105, the oxide semiconductor film 107, the first terminal 109, and the second terminal 111.

Next, the gate 115 is formed over the insulating film 113.

Through the above steps, the power device 120 including the oxide semiconductor film 107 having a crystalline structure for the channel region can be manufactured. Lastly, the power device 120 is fixed to the heat dissipation plate 101.

### Embodiment 2

In Embodiment 1, examples of three-terminal power devices are described; in this embodiment, an example of a two-terminal power device will be described.

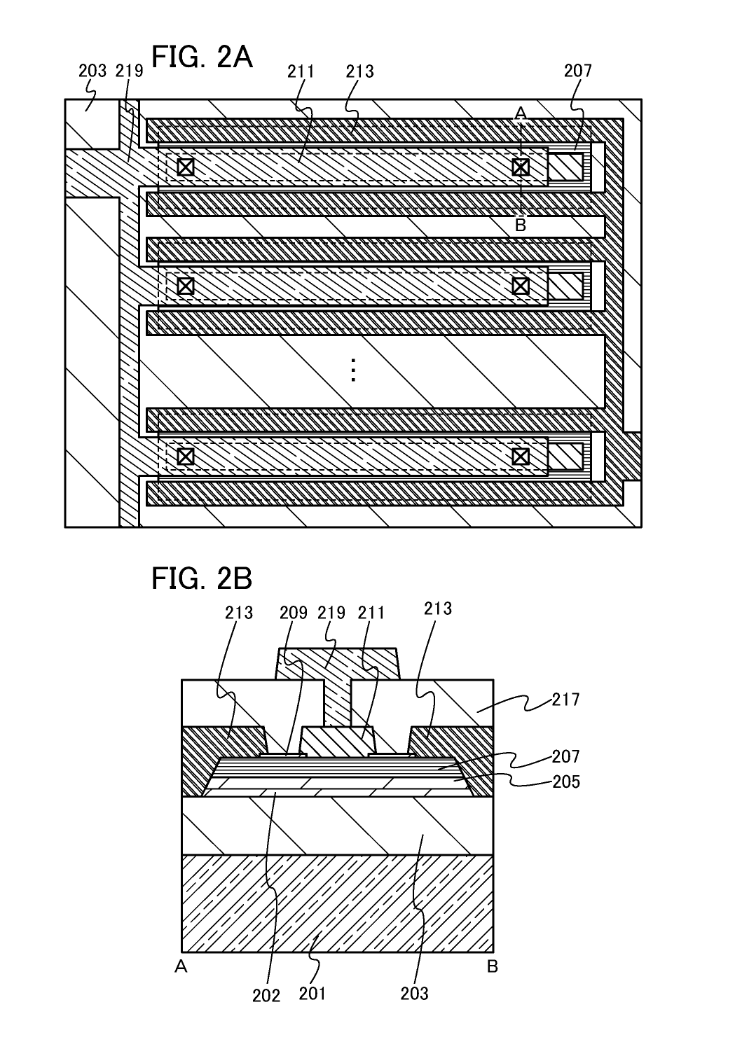

FIG. 2A is a top view of a power device illustrated in FIG. 2B. A cross-sectional view taken along a chained line A-B in FIG. 2A corresponds to FIG. 2B.

In the two-terminal power device illustrated in FIG. 2B, a semiconductor substrate 203 serves as a first terminal, an insulating film 202 is provided over the semiconductor substrate 203, a buffer layer 205 is provided over the insulating film 202, an oxide semiconductor film 207 having a crystalline structure is provided over the buffer layer 205, a conductive layer 213 is provided so as to partly cover the oxide semiconductor film 207 having a crystalline structure, a protective layer 209 is provided in contact with the oxide semiconductor film 207 having a crystalline structure, and a second terminal 211 is formed over and in contact with the oxide semiconductor film 207 having a crystalline structure. The second terminal 211 is electrically connected to a lead wiring 219 over an interlayer insulating film 217.

As the semiconductor substrate 203, a single crystal silicon substrate, a SiC substrate, a GaN substrate, a GaAs substrate, or the like is used. Alternatively, a compound semiconductor substrate of silicon germanium or the like or an SOI substrate may be used as the semiconductor substrate 203.

The insulating film 202 can be a single insulating film or a stack of insulating films selected from a silicon oxide film which is obtained by thermal oxidation or the like using hydrogen chloride or the like and a silicon oxide film, an oxynitride insulating film of silicon oxynitride, aluminum oxynitride, or the like, and a nitride oxide insulating film of silicon nitride oxide or the like which are obtained by a plasma CVD method or the like.

As the insulating film 202, a silicon nitride film obtained by a plasma CVD method or the like may be used. Note that in the case of using a silicon nitride film, it is preferable to use a silicon nitride film from which hydrogen or a hydrogen compound is hardly released by heat treatment after film formation, such as a silicon nitride film formed using a mixed gas of silane (SiH₄), nitrogen (N₂), and ammonia (NH₃) as a supply gas.

The buffer layer 205 can be formed using a single insulating film or a stack of insulating films selected from oxide insulating films of gallium oxide, indium gallium oxide, hafnium oxide, yttrium oxide, aluminum oxide, and the like. Among these materials, gallium oxide or indium gallium oxide containing a constituent element of the oxide semiconductor film is preferable. Alternatively, the buffer layer 205 may be formed using an In—Ga—Zn-based oxide film which is formed using a target with an atomic ratio of In:Ga:Zn=1:3:2.

The oxide semiconductor film 207 having a crystalline structure can be formed using an oxide containing at least In and containing a metal element M (M is Ga, Hf, Zn, Mg, Sn, or the like), e.g., a two-component metal oxide such as an In—Zn-based oxide, an In—Mg-based oxide, or an In—Ga-based oxide, a three-component metal oxide such as an In—Ga—Zn-based oxide (also referred to as IGZO), an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, or an In—Sn—Hf—Zn-based oxide.

The conductive layer 213 can be formed using a metal element selected from aluminum, chromium, copper, tantalum, titanium, molybdenum, and tungsten; an alloy containing any of these metal elements as a component; an alloy containing these metal elements in combination; or the like. Further, one or more metal elements selected from manganese, magnesium, zirconium, and beryllium may be used. In addition, the conductive layer 213 may have a single-layer structure or a stacked-layer structure of two or more layers. For example, a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, a three-layer structure in which a titanium layer, an aluminum layer, and a titanium layer are stacked in this order, and the like can be given. Alternatively, a layer, an alloy layer, or a nitride layer, which contains aluminum and one or more elements selected from titanium, tantalum, tungsten, molybdenum, chromium, neodymium, and scandium may be used.

The protective layer 209 can be a single insulating film or a stack of insulating films selected from a silicon oxide film, an oxynitride insulating film of silicon oxynitride, aluminum oxynitride, or the like, and a nitride oxide insulating film of silicon nitride oxide or the like which are obtained by a plasma CVD method or the like. Note that the protective layer 209 is provided in order to protect a surface of the oxide semiconductor film 207 having a crystalline structure, and when not needed, it is not necessarily provided.

The second terminal 211 can be formed using a metal element selected from aluminum, chromium, copper, tantalum, titanium, molybdenum, and tungsten; an alloy containing any of these metal elements as a component; an alloy containing these metal elements in combination; or the like.

The power device illustrated in FIG. 2B can function as a rectifier element using the oxide semiconductor film 207 having a crystalline structure.

A method for manufacturing the power device illustrated in FIG. 2B will be described below.

The insulating film 202 is formed over the semiconductor substrate 203 serving as a first terminal. As the insulating film 202, an insulating film which is dense and has high withstand voltage and high quality is formed by high-density plasma CVD using microwaves (e.g., a frequency of 2.45 GHz). Alternatively, the insulating film 202 may be formed by thermal oxidation using hydrogen chloride.

Next, the buffer layer 205 is formed by a sputtering method, a CVD method, a coating method, a pulsed laser deposition method, or the like. As the buffer layer 205, a material film capable of blocking the diffusion of impurities contained in the semiconductor substrate 203 or the insulating film 202, typically a film containing gallium, is used.

Next, the oxide semiconductor film 207 having a crystalline structure is formed over the buffer layer 205.

The oxide semiconductor film 207 is preferably the one having a crystal structure right after deposition, which is obtained by deposition by a sputtering method at a relatively high deposition temperature. If the deposition temperature is set at 400° C. or higher for high density, later heat treatment at 900° C. or higher does not generate peeling or the like. Note that in the case where the oxide semiconductor film 207 has low crystallinity right after the deposition, the oxide semiconductor film 207 can be changed to have high crystallinity by performing heat treatment thereon.

In this embodiment, a CAAC-OS film is formed at a substrate temperature of 400° C. using an In—Ga—Zn-based oxide film which is formed using a target with an atomic ratio of In:Ga:Zn=3:1:2, and is then subjected to heat treatment at 950° C. Even after the heat treatment, in the oxide semiconductor film 207, a c-axis is aligned in a direction parallel to a normal vector of a surface where the oxide semiconductor film is formed or a normal vector of a surface of the oxide semiconductor film, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis.

Then, heat treatment is performed at a temperature higher than or equal to 900° C. and lower than or equal to 1500° C. in a vacuum atmosphere, a nitrogen atmosphere, an oxygen atmosphere, or a mixed atmosphere of nitrogen and oxygen. With the heat treatment at a temperature higher than or equal to 900° C. and lower than or equal to 1500° C., density and crystallinity which are in substantially the same level as those of a single crystal of an oxide semiconductor can be obtained.

Note that when the buffer layer 205 is exposed to a clean room atmosphere after the formation and then the oxide semiconductor film is formed, boron contained in the clean room atmosphere might be mixed at the interface between the buffer layer 205 and the oxide semiconductor film. Thus, it is preferable that the oxide semiconductor film be formed without exposure of the buffer layer 205 to the atmosphere after the formation. Both of them can be formed by a sputtering method and can be successively formed simply by changing targets.

Next, the protective layer 209 is formed over the oxide semiconductor film 207, a resist is formed by a photolithography process, and the protective layer 209 is etched with the use of the resist as a mask.

Next, a resist is formed by a photolithography process over the oxide semiconductor film 207 having a crystalline structure, and the oxide semiconductor film is etched using the resist as a mask. Thus, an island-shaped oxide semiconductor film is formed. The island-shaped oxide semiconductor film is formed so as to have a tapered side surface. Note that the taper angle between the side surface of the oxide semiconductor film 207 having a crystalline structure and a surface of the semiconductor substrate is greater than or equal to 10° and less than or equal to 70°.

Next, the second terminal 211 is formed in such a manner that a conductive layer is formed over the oxide semiconductor film 207 by a sputtering method, a CVD method, an evaporation method, or the like, and then the conductive layer is etched with the use of a resist formed by a photolithography process as a mask.

Next, the conductive layer 213 is formed in such a manner that a conductive layer is formed over the oxide semiconductor film 207 by a sputtering method, a CVD method, an evaporation method, or the like, and then the conductive layer is etched with the use of a resist formed by a photolithography process as a mask.

Next, the interlayer insulating film 217 is formed over the protective layer 209 and the second terminal 211.

The interlayer insulating film 217 can be a single insulating film or a stack of insulating films selected from a silicon oxide film, an oxynitride insulating film of silicon oxynitride, aluminum oxynitride, or the like, and a nitride oxide insulating film of silicon nitride oxide or the like which are obtained by a plasma CVD method or the like.

Next, the lead wiring 219 is formed over the interlayer insulating film 217. The lead wiring 219 can be formed in such a manner that openings are formed in the interlayer insulating film 217, a conductive layer is formed over the interlayer insulating film 217 by a sputtering method, a CVD method, an evaporation method, or the like, and then the conductive layer is etched with the use of a resist formed by a photolithography process as a mask.

Through the above steps, the power device including the oxide semiconductor film 207 having a crystalline structure can be manufactured. Lastly, the power device is fixed to a heat dissipation plate 201.

As illustrated in FIG. 2A, a plurality of power devices can be connected in parallel.

### Embodiment 3

In Embodiment 1, examples of power MOSFETs are described; in this embodiment, an example of a power MESFET will be described.

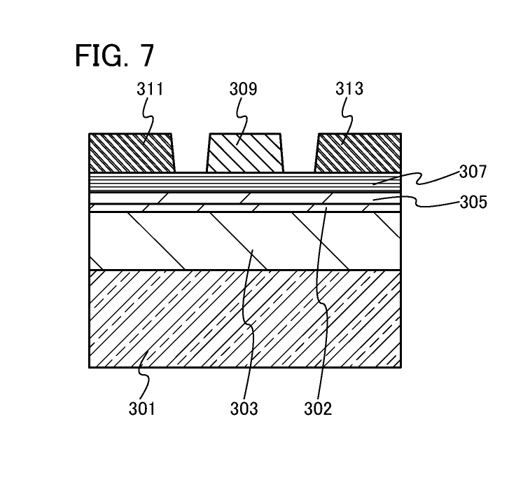

FIG. 7 is an example of a cross-sectional view of a power MESFET.

In the power MESFET illustrated in FIG. 7, an insulating film 302 is provided over a semiconductor substrate 303, a buffer layer 305 is provided over the insulating film 302, an oxide semiconductor film 307 having a crystalline structure is provided over the buffer layer 305, and a gate 309, a first terminal 311, and a second terminal 313 are formed using a conductive layer so as to cover part of the oxide semiconductor film 307 having a crystalline structure. Note that the first terminal 311 is a source electrode and the second terminal 313 is a drain electrode.

It is necessary that the semiconductor substrate 303 have at least heat resistance high enough to withstand heat treatment (900° C. or higher) which is performed later.

As the semiconductor substrate 303, a single crystal silicon substrate, a SiC substrate, a GaN substrate, a GaAs substrate, or the like is used. Alternatively, a compound semiconductor substrate of silicon germanium or the like or an SOI substrate may be used as the semiconductor substrate 303.

The insulating film 302 can be a single insulating film or a stack of insulating films selected from a silicon oxide film which is obtained by thermal oxidation or the like using hydrogen chloride or the like and a silicon oxide film, an oxynitride insulating film of silicon oxynitride, aluminum oxynitride, or the like, and a nitride oxide insulating film of silicon nitride oxide or the like which are obtained by a plasma chemical vapor deposition (CVD) method or the like.

As the insulating film 302, a silicon nitride film obtained by a plasma CVD method or the like may be used. Note that in the case of using a silicon nitride film, it is preferable to use a silicon nitride film from which hydrogen or a hydrogen compound is hardly released by heat treatment after film formation, such as a silicon nitride film formed using a mixed gas of silane (SiH₄), nitrogen (N₂), and ammonia (NH₃) as a supply gas.

The buffer layer 305 can be formed using a single insulating film or a stack of insulating films selected from oxide insulating films of gallium oxide, indium gallium oxide, hafnium oxide, yttrium oxide, aluminum oxide, and the like. Among these materials, gallium oxide or indium gallium oxide containing a constituent element of the oxide semiconductor film is preferable. Alternatively, the buffer layer 305 may be formed using an In—Ga—Zn-based oxide film which is formed using a target with an atomic ratio of In:Ga:Zn=1:3:2.

The oxide semiconductor film 307 having a crystalline structure can be formed using an oxide containing at least In and containing a metal element M (M is Ga, Hf, Zn, Mg, Sn, or the like), e.g., a two-component metal oxide such as an In—Zn-based oxide, an In—Mg-based oxide, or an In—Ga-based oxide, a three-component metal oxide such as an In—Ga—Zn-based oxide (also referred to as IGZO), an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, or an In—Sn—Hf—Zn-based oxide.

The first terminal 311 and the second terminal 313 can be formed using a metal element selected from aluminum, chromium, copper, tantalum, titanium, molybdenum, and tungsten; an alloy containing any of these metal elements as a component; an alloy containing these metal elements in combination; or the like. Further, one or more metal elements selected from manganese, magnesium, zirconium, and beryllium may be used. In addition, the first terminal 311 and the second terminal 313 may have a single-layer structure or a stacked-layer structure of two or more layers.

The gate 309 can be formed using a metal element selected from aluminum, chromium, copper, tantalum, titanium, molybdenum, and tungsten; an alloy containing any of these metal elements as a component; an alloy containing these metal elements in combination; or the like. Further, one or more metal elements selected from manganese, magnesium, zirconium, and beryllium may be used. In addition, the gate 309 may have a single-layer structure or a stacked-layer structure of two or more layers. For example, a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, a three-layer structure in which a titanium layer, an aluminum layer, and a titanium layer are stacked in this order, and the like can be given. Alternatively, a layer, an alloy layer, or a nitride layer, which contains aluminum and one or more elements selected from titanium, tantalum, tungsten, molybdenum, chromium, neodymium, and scandium may be used.

Note that the gate 309 is preferably formed using a material different from that of the first terminal 311 and the second terminal 313.

A method for manufacturing the power MESFET illustrated in FIG. 7 will be described below.

The insulating film 302 is formed over the semiconductor substrate 303. The insulating film 302 is formed by thermal oxidation using hydrogen chloride. Alternatively, the insulating film 302 may be formed by high-density plasma CVD using microwaves (e.g., a frequency of 2.45 GHz) so as to be dense and have high withstand voltage and high quality.

Next, the buffer layer 305 is formed by a sputtering method, a CVD method, a coating method, a pulsed laser deposition method, or the like. As the buffer layer 305, a material film capable of blocking the diffusion of impurities contained in the semiconductor substrate 303 or the insulating film 302, typically a film containing gallium, is used.

Next, the oxide semiconductor film 307 having a crystalline structure is formed over the buffer layer 305.

The oxide semiconductor film 307 is preferably the one having a crystal structure right after deposition, which is obtained by deposition by a sputtering method at a relatively high deposition temperature. If the deposition temperature is set at 400° C. or higher for high density, later heat treatment at 900° C. or higher does not generate peeling or the like. Note that in the case where the oxide semiconductor film 307 has low crystallinity right after the deposition, the oxide semiconductor film 307 can be changed to have high crystallinity by performing heat treatment thereon.

Then, heat treatment is performed at a temperature higher than or equal to 900° C. and lower than or equal to 1500° C. in a vacuum atmosphere, a nitrogen atmosphere, an oxygen atmosphere, or a mixed atmosphere of nitrogen and oxygen. With the heat treatment at a temperature higher than or equal to 900° C. and lower than or equal to 1500° C., density and crystallinity which are in substantially the same level as those of a single crystal of an oxide semiconductor can be obtained.

In this embodiment, a CAAC-OS film is formed at a substrate temperature of 400° C. using an In—Ga—Zn-based oxide film which is formed using a target with an atomic ratio of In:Ga:Zn=1:1:1, and is then subjected to heat treatment at 950° C. Even after the heat treatment, in the oxide semiconductor film 307, a c-axis is aligned in a direction parallel to a normal vector of a surface where the oxide semiconductor film is formed or a normal vector of a surface of the oxide semiconductor film, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis.

Note that when the buffer layer 305 is exposed to a clean room atmosphere after the formation and then the oxide semiconductor film is formed, boron contained in the clean room atmosphere might be mixed at the interface between the buffer layer 305 and the oxide semiconductor film. Thus, it is preferable that the oxide semiconductor film be formed without exposure of the buffer layer 305 to the atmosphere after the formation. Both of them can be formed by a sputtering method and can be successively formed simply by changing targets.

Next, the gate 309 is formed in such a manner that a conductive layer is formed over the oxide semiconductor film 307 by a sputtering method, a CVD method, an evaporation method, or the like, and then the conductive layer is etched with the use of a resist formed by a photolithography process as a mask.

Next, the first terminal 311 and the second terminal 313 are formed in such a manner that a conductive layer is formed over the oxide semiconductor film 307 by a sputtering method, a CVD method, an evaporation method, or the like, and then the conductive layer is etched with the use of a resist formed by a photolithography process as a mask.

Through the above steps, the power MESFET including the oxide semiconductor film 307 having a crystalline structure for the channel region can be manufactured. Lastly, the power MESFET is fixed to a heat dissipation plate 301.

### Embodiment 4

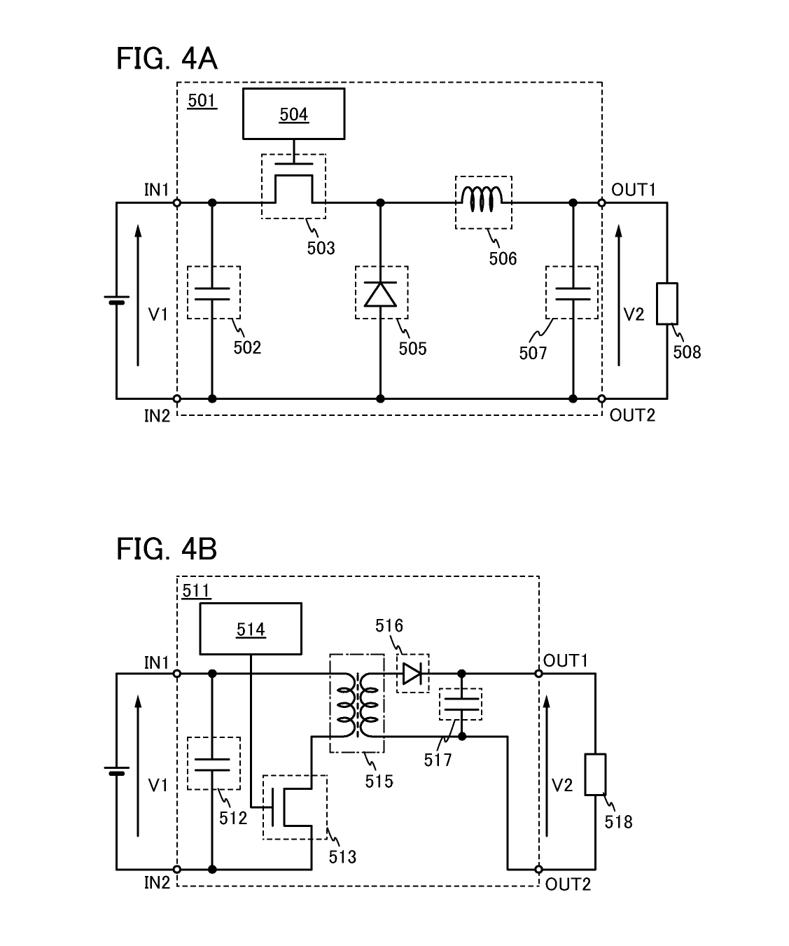

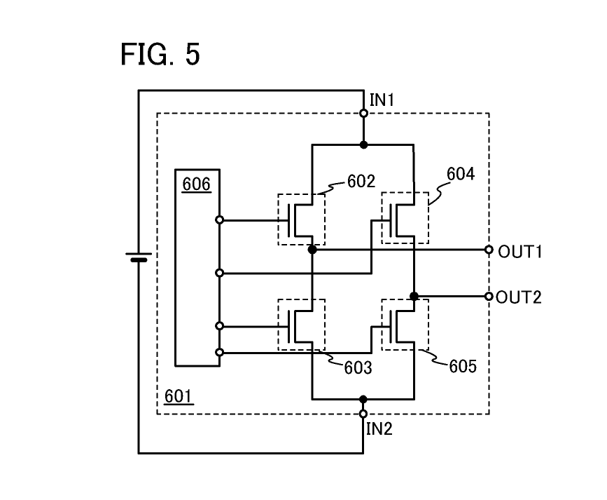

In this embodiment, embodiments of the configurations of power converter circuits such as an inverter and a converter including the transistor described in Embodiment 1 or 3 or the rectifier element described in Embodiment 2 will be described. In this embodiment, FIGS. 4A and 4B each illustrate an example of the circuit configuration of a DC-DC converter, and FIG. 5 shows an example of the circuit configuration of an inverter.

A DC-DC converter 501 in FIG. 4A is an example of a step-down DC-DC converter using a chopper circuit. The DC-DC converter 501 includes a capacitor 502, an FET 503, a control circuit 504, a diode 505, a coil 506, and a capacitor 507.

The DC-DC converter 501 in FIG. 4A is operated by a switching operation of the FET 503 with the control circuit 504. By the DC-DC converter 501, an input voltage V1 applied to input terminals IN1 and IN2 can be output from output terminals OUT1 and OUT2 to a load 508 as a voltage V2 which is stepped down. The semiconductor device described in the above embodiment can be applied to the FET 503 included in the DC-DC converter 501. Therefore, high output current can flow through the DC-DC converter 501 by the switching operation, and off-state current can be reduced. Accordingly, the DC-DC converter consumes less power and can operate at high speed.

Although a step-down DC-DC converter using a chopper circuit is shown in FIG. 4A as an example of a non-isolated power converter circuit, the semiconductor device described in the above embodiment can also be applied to an FET included in a step-up DC-DC converter using a chopper circuit or a step-up/step-down DC-DC converter using a chopper circuit. Therefore, high output current can flow through the DC-DC converter by the switching operation, and off-state current can be reduced. Accordingly, the DC-DC converter consumes less power and can operate at high speed.

Next, a DC-DC converter 511 illustrated in FIG. 4B is an example of a fly-back converter which is an isolated power converter circuit. The DC-DC converter 511 includes a capacitor 512, an FET 513, a control circuit 514, a transformer 515 including a primary coil and a secondary coil, a diode 516, and a capacitor 517.

The DC-DC converter 511 in FIG. 4B is operated by a switching operation of the FET 513 with the control circuit 514. By the DC-DC converter 511, an input voltage V1 applied to input terminals IN1 and IN2 can be output from output terminals OUT1 and OUT2 to a load 518 as a voltage V2 which is stepped up or stepped down. The semiconductor device described in the above embodiment can be applied to the FET 513 included in the DC-DC converter 511. Therefore, high output current can flow through the DC-DC converter 511 by the switching operation, and off-state current can be reduced. Accordingly, the DC-DC converter consumes less power and can operate at high speed.

Note that the semiconductor device described in the above embodiment can also be applied to an FET included in a forward DC-DC converter.

An inverter 601 in FIG. 5 is an example of a full-bridge inverter. The inverter 601 includes an FET 602, an FET 603, an FET 604, an FET 605, and a control circuit 606.

The inverter 601 in FIG. 5 is operated by switching operations of the FETs 602 to 605 with the control circuit 606. A direct-current voltage V1 applied to input terminals IN1 and IN2 can be output from output terminals OUT1 and OUT2 as an alternating-current voltage V2. The semiconductor device described in the above embodiment can be applied to the FETs 602 to 605 included in the inverter 601. Therefore, high output current can flow through the inverter 601 by the switching operations, and off-state current can be reduced. Accordingly, the inverter consumes less power and can operate at high speed.

Note that what is illustrated in the drawings in this embodiment can be freely combined with or replaced with what is described in another embodiment as appropriate.

### Embodiment 5

In this embodiment, applications of the power converter circuit of Embodiment 4 will be described. The power converter circuit such as the converter or the inverter of Embodiment 4 can be used, for example, in an electric vehicle which operates with electric power such as battery power.

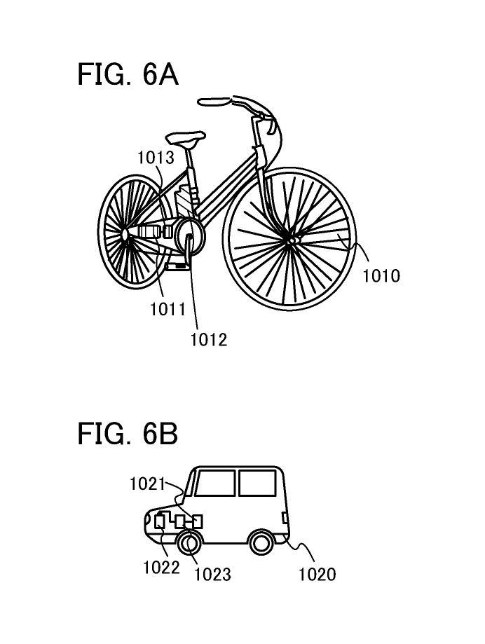

Application examples of electric vehicles are described with reference to FIGS. 6A and 6B.

FIG. 6A illustrates an electric bicycle 1010 as an application example of an electric vehicle including a power converter circuit. The electric bicycle 1010 obtains power when current flows through a motor unit 1011. The electric bicycle 1010 includes a battery 1012 and a power converter circuit 1013 which are used to feed current to the motor unit 1011. Although not illustrated, an additional electric generator or the like may be provided in the electric bicycle 1010 in FIG. 6A for the purpose of charging the battery 1012. The power converter circuit described in Embodiment 4 can be used as the power converter circuit 1013 illustrated in FIG. 6A. Therefore, by the power device included in the power converter circuit 1013, power consumption is reduced and high-speed operation can be achieved, so that the electric bicycle 1010 can be driven with fewer defects. Note that although a pedal is illustrated in FIG. 6A, the pedal is not necessarily provided.

FIG. 6B illustrates an electric car 1020 as an application example of an electric vehicle including a power converter circuit. The electric car 1020 obtains power when current flows through a motor unit 1021. The electric car 1020 includes a battery 1022 and a power converter circuit 1023 which are used to feed current to the motor unit 1021. Although not illustrated, an additional electric generator or the like may be provided in the electric car 1020 in FIG. 6B for the purpose of charging the battery 1022. The power converter circuit described in Embodiment 4 can be used as the power converter circuit 1023 illustrated in FIG. 6B. Therefore, by the power device included in the power converter circuit 1023, power consumption is reduced and high-speed operation can be achieved, so that the electric car 1020 can be driven with fewer defects.

Note that what is illustrated in the drawings in this embodiment can be freely combined with or replaced with what is described in another embodiment as appropriate.

### Embodiment 6

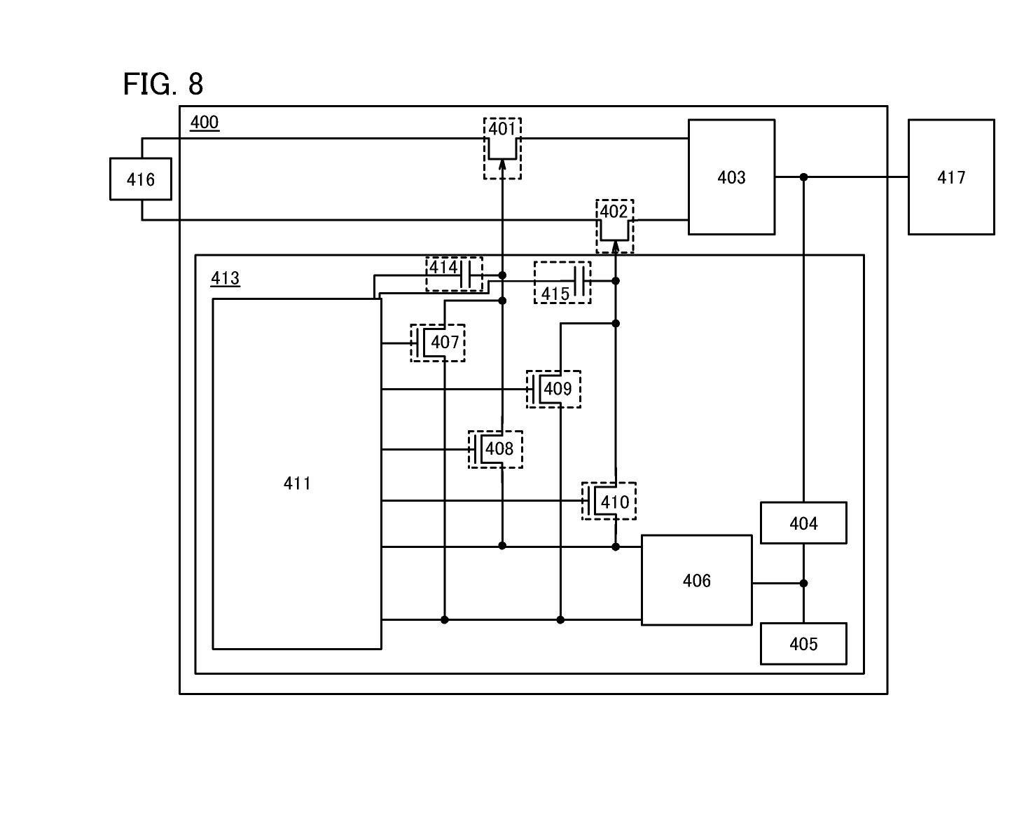

FIG. 8 illustrates a configuration example of a power supply circuit 400 according to one embodiment of the present invention. The power supply circuit 400 in FIG. 8 includes a control circuit 413, a power switch 401, a power switch 402, and a voltage regulator 403.

Voltage is supplied from a power supply 416 to the power supply circuit 400. The power switches 401 and 402 each have a function of controlling input of the voltage to the voltage regulator 403.

Note that in the case where the voltage output from the power supply 416 is AC voltage, as illustrated in FIG. 8, the power switch 401 controlling input of a first potential to the voltage regulator 403 and the power switch 402 controlling input of a second potential to the voltage regulator 403 are provided in the power supply circuit 400. In the case where the voltage output from the power supply 416 is DC voltage, as illustrated in FIG. 8, the power switch 401 controlling input of the first potential to the voltage regulator 403 and the power switch 402 controlling input of the second potential to the voltage regulator 403 may be provided in the power supply circuit 400; alternatively, the second potential may be a ground potential, the power switch 402 controlling input of the second potential to the voltage regulator 403 may be eliminated, and the power switch 401 controlling input of the first potential to the voltage regulator 403 may be provided in the power supply circuit 400.

In one embodiment of the present invention, a transistor having high withstand voltage is used as each of the power switches 401 and 402. Specifically, the power MOSFET in Embodiment 1 or the power MESFET in Embodiment 3 can be used as the transistor.

The power switches 401 and 402 can each have high withstand voltage when including the oxide semiconductor film having a crystalline structure.

The use of a field-effect transistor including the above transistor material in an active layer as the power switch 401 or 402 can achieve high-speed switching of the power switch 401 or 402, compared with a field-effect transistor including silicon carbide or gallium nitride in an active layer. Consequently, power loss due to the switching can be reduced.

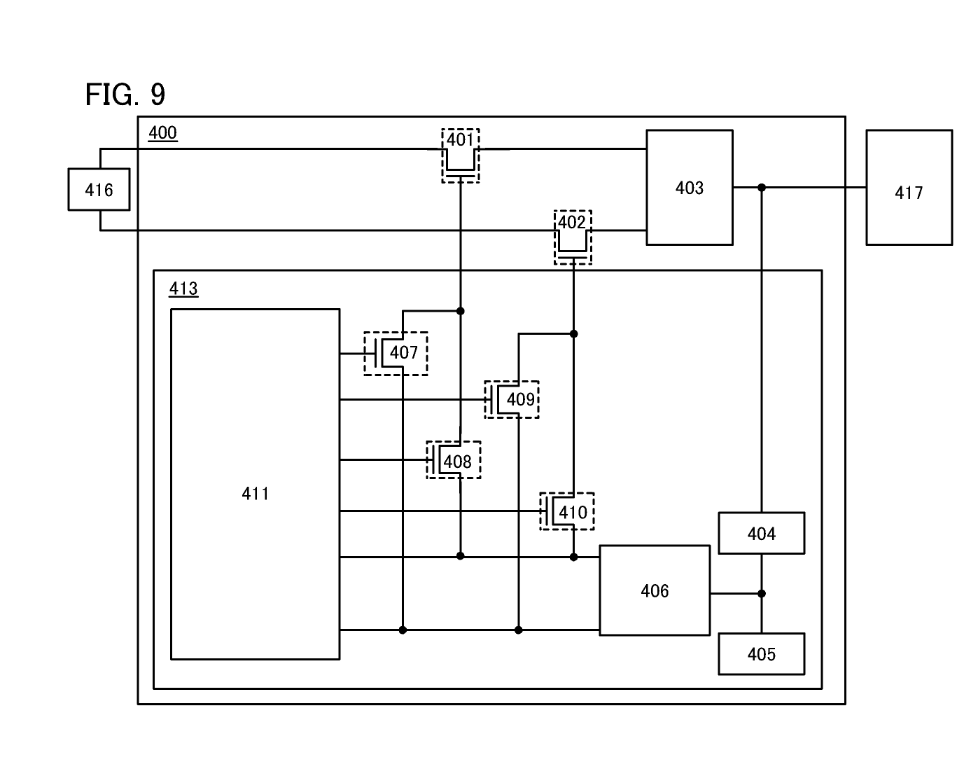

Note that FIG. 8 illustrates an example of using MESFETs as the power switches 401 and 402. However, the present invention is not limited to this example, and MOSFETs may be used as the power switches 401 and 402 as illustrated in FIG. 9, for example.

The voltage regulator 403 has a function of regulating voltage input from the power supply 416 through the power switches 401 and 402. Specifically, voltage regulation in the voltage regulator 403 means any one or more of conversion of AC voltage into DC voltage, change of a voltage level, smoothing of a voltage level, and the like.

Voltage regulated in the voltage regulator 403 is applied to a load 417 and the control circuit 413.

In addition, the power supply circuit 400 in FIG. 8 includes a power storage device 404, an auxiliary power supply 405, a voltage generation circuit 406, transistors 407 to 410, and capacitors 414 and 415.

The power storage device 404 has a function of temporarily storing power supplied from the voltage regulator 403. Specifically, the power storage device 404 includes a power storage portion such as a capacitor or a secondary battery that can store power with the use of voltage applied from the voltage regulator 403.

The auxiliary power supply 405 has a function of compensating for the lack of power output from the power storage device 404 for operation of the control circuit 413. A primary battery or the like can be used as the auxiliary power supply 405.

The voltage generation circuit 406 has a function of generating voltage for controlling switching of the power switches 401 and 402 with the use of voltage output from the power storage device 404 or the auxiliary power supply 405. Specifically, the voltage generation circuit 406 has a function of generating voltage for turning on the power switches 401 and 402 and a function of generating voltage for turning off the power switches 401 and 402.

A wireless signal input circuit 411 has a function of controlling the power switches 401 and 402 in accordance with switching of the transistors 407 to 410.

Specifically, the wireless signal input circuit 411 includes an input portion that converts an instruction superimposed on a wireless signal given from the outside to control the operating states of the power switches 401 and 402 into an electric signal, and a signal processor that decodes the instruction included in the electric signal and generates a signal for controlling the switching of the transistors 407 to 410 in accordance with the instruction.

The transistors 407 to 410 switch in accordance with the signal generated in the wireless signal input circuit 411. Specifically, when the transistors 408 and 410 are on, the voltage for turning on the power switches 401 and 402 that is generated in the voltage generation circuit 406 is applied to the power switches 401 and 402. When the transistors 408 and 410 are off, the voltage for turning on the power switches 401 and 402 is continuously applied to the power switches 401 and 402. Further, when the transistors 407 and 409 are on, the voltage for turning off the power switches 401 and 402 that is generated in the voltage generation circuit 406 is applied to the power switches 401 and 402. When the transistors 407 and 409 are off, the voltage for turning off the power switches 401 and 402 is continuously applied to the power switches 401 and 402.

In one embodiment of the present invention, a transistor with extremely low off-state current is used as each of the transistors 407 to 410 so that the voltage is continuously applied to the power switches 401 and 402. With this structure, even when generation of the voltage for determining the operating states of the power switches 401 and 402 in the voltage generation circuit 406 is stopped, the operating states of the power switches 401 and 402 can be kept. Thus, the power consumption of the voltage generation circuit 406 is reduced, so that the power consumption of the power supply circuit 400 can be reduced.

Note that the transistors 407 to 410 may be provided with back gates, which are supplied with a potential, in order to control the threshold voltages of the transistors 407 to 410.

Since a transistor including a wide-gap semiconductor whose bandgap is two or more times that of silicon in an active layer has extremely low off-state current, the transistor is preferably used as each of the transistors 407 to 410. For example, an oxide semiconductor or the like can be used as the wide-gap semiconductor.

Note that a purified oxide semiconductor (purified OS) obtained by reduction of impurities such as moisture or hydrogen which serves as an electron donor (donor) and by reduction of oxygen defects is an intrinsic (i-type) semiconductor or a substantially i-type semiconductor. Thus, with the use of an oxide semiconductor film which is purified by sufficiently reducing the concentration of impurities such as moisture or hydrogen and by reducing oxygen defects, off-state current of the transistor can be reduced. Consequently, the use of a transistor including a purified oxide semiconductor film as each of the transistors 407 to 410 reduces the power consumption of the voltage generation circuit 406, so that the effect of reducing the power consumption of the power supply circuit 400 can be increased.

Various experiments can actually prove low off-state current of the transistor including the purified oxide semiconductor in an active layer. For example, even with an element with a channel width of 1×10⁶ μm and a channel length of 10 μm, in a range of from 1 V to 10 V of voltage (drain voltage) between a source electrode and a drain electrode, it is possible that off-state current is less than or equal to the measurement limit of a semiconductor parameter analyzer, that is, less than or equal to 1×10⁻¹³ A. In this case, it can be seen that an off-state current standardized on the channel width of the transistor is lower than or equal to 100 zA/μm. Further, an off-state current has been measured with the use of a circuit in which a capacitor and a transistor are connected to each other and charge that flows into the capacitor or flows out of the capacitor is controlled by the transistor. In the measurement, a purified oxide semiconductor film has been used for a channel formation region of the transistor, and an off-state current of the transistor has been measured from a change in the amount of charge of the capacitor per unit time. As a result, it is found that, in the case where the voltage between the source electrode and the drain electrode of the transistor is 3 V, a lower off-state current of several tens of yA/μm is obtained. Accordingly, the off-state current of the transistor in which the purified oxide semiconductor film is used for a channel formation region is considerably lower than that of a transistor in which silicon having crystallinity is used.

Among the oxide semiconductors, unlike silicon carbide or gallium nitride, an In—Ga—Zn-based oxide, an In—Sn—Zn-based oxide, or the like has an advantage of high mass productivity because a transistor with favorable electrical characteristics can be formed by a sputtering method or a wet process. Further, unlike silicon carbide or gallium nitride, the oxide semiconductor (the In—Ga—Zn-based oxide) can be deposited even at room temperature; thus, a transistor with favorable electrical characteristics can be formed over a glass substrate or an integrated circuit using silicon. Furthermore, a larger substrate can be used.

The capacitor 414 has a function of holding voltage applied to the power switch 401 when the transistors 407 and 408 are off. The capacitor 415 has a function of holding voltage applied to the power switch 402 when the transistors 409 and 410 are off. One of a pair of electrodes of each of the capacitors 414 and 415 is connected to the wireless signal input circuit 411. Note that as illustrated in FIG. 9, the capacitors 414 and 415 are not necessarily provided.

When the power switches 401 and 402 are on, voltage is supplied from the power supply 416 to the voltage regulator 403. In addition, with the voltage, power is stored in the power storage device 404.

When the power switches 401 and 402 are off, supply of voltage from the power supply 416 to the voltage regulator 403 is stopped. Thus, although power is not supplied to the power storage device 404, the control circuit 413 can be operated using power stored in the power storage device 404 or the auxiliary power supply 405 in one embodiment of the present invention, as described above. In other words, in the power supply circuit 400 according to one embodiment of the present invention, supply of voltage to the voltage regulator 403 can be stopped while the operating states of the power switches 401 and 402 are controlled by the control circuit 413. By stopping the supply of voltage to the voltage regulator 403, it is possible to prevent power consumption due to charging and discharging of the capacitance of the voltage regulator 403 when voltage is not supplied to the load 417. Consequently, the power consumption of the power supply circuit 400 can be reduced.

This application is based on Japanese Patent Application serial no. 2012-126607 filed with Japan Patent Office on Jun. 1, 2012, the entire contents of which are hereby incorporated by reference.

What is claimed is:

1. A method for manufacturing a semiconductor device, comprising the steps of:
forming an oxide insulating film over a semiconductor substrate;
forming a buffer layer over the oxide insulating film;
forming an oxide semiconductor film over the buffer layer; and
performing heat treatment on the oxide semiconductor film at a temperature higher than or equal to 900° C. and lower than or equal to 1500° C., thereby forming an oxide semiconductor film having a crystalline structure.

2. The method for manufacturing a semiconductor device according to claim 1, wherein the semiconductor substrate is a single crystal silicon substrate and the oxide insulating film is a thermal oxide film.

3. The method for manufacturing a semiconductor device according to claim 1, wherein in a crystal part included in the oxide semiconductor film having the crystalline structure, a c-axis is aligned in a direction parallel to a normal vector of a surface where the oxide semiconductor film is formed or a normal vector of a surface of the oxide semiconductor film, triangular or hexagonal atomic arrangement which is seen from a direction perpendicular to an a-b plane is formed, and metal atoms are arranged in a layered manner or metal atoms and oxygen atoms are arranged in a layered manner when seen from a direction perpendicular to the c-axis.

4. The method for manufacturing a semiconductor device according to claim 1, wherein the buffer layer is a film comprising gallium.

5. A method for manufacturing a semiconductor device, comprising the steps of:
forming an oxide insulating film over a semiconductor substrate;
forming a buffer layer over the oxide insulating film;
forming an oxide semiconductor film having a crystalline structure over the buffer layer;
selectively adding phosphorus, boron, or nitrogen to the oxide semiconductor film having the crystalline structure; and
performing heat treatment on the oxide semiconductor film at a temperature higher than or equal to 900° C. and lower than or equal to 1500° C. after adding phosphorus, boron, or nitrogen.

6. The method for manufacturing a semiconductor device according to claim 5, wherein the semiconductor substrate is a single crystal silicon substrate and the oxide insulating film is a thermal oxide film.

7. The method for manufacturing a semiconductor device according to claim 5, wherein in a crystal part included in the oxide semiconductor film having the crystalline structure, a c-axis is aligned in a direction parallel to a normal vector of a surface where the oxide semiconductor film is formed or a normal vector of a surface of the oxide semiconductor film, triangular or hexagonal atomic arrangement which is seen from a direction perpendicular to an a-b plane is formed, and metal atoms are arranged in a layered manner or metal atoms and oxygen atoms are arranged in a layered manner when seen from a direction perpendicular to the c-axis.

8. The method for manufacturing a semiconductor device according to claim 5, wherein the buffer layer is a film comprising gallium.

9. A semiconductor device comprising:
an oxide insulating film over a semiconductor substrate;
a buffer layer over the oxide insulating film; and
an oxide semiconductor film having a crystalline structure over the buffer layer.

10. The semiconductor device according to claim 9, wherein the semiconductor substrate is a single crystal silicon substrate and the oxide insulating film is a thermal oxide film.

11. A semiconductor device comprising:
a nitride insulating film over a semiconductor substrate;
a buffer layer over the nitride insulating film; and
an oxide semiconductor film having a crystalline structure over the buffer layer.

12. The semiconductor device according to claim 9, wherein in a crystal part included in the oxide semiconductor film having the crystalline structure, a c-axis is aligned in a direction parallel to a normal vector of a surface where the oxide semiconductor film is formed or a normal vector of a surface of the oxide semiconductor film, triangular or hexagonal atomic arrangement which is seen from a direction perpendicular to an a-b plane is formed, and metal atoms are arranged in a layered manner or metal atoms and oxygen atoms are arranged in a layered manner when seen from a direction perpendicular to the c-axis.

13. The semiconductor device according to claim 9, wherein the buffer layer is a film comprising gallium.

14. The semiconductor device according to claim 9, wherein the buffer layer is a film comprising indium, gallium, and zinc.
